(19) United States
(12) Patent Application Publication
(10) Pub. No.: US 2012/0139073 A1
(43) Pub. Date: Jun. 7, 2012

(54) METHOD FOR FABRICATING AT LEAST ONE DETECTOR PIXEL CELL, SENSOR COMPRISING AT LEAST ONE SUCH CELL

(76) Inventor: Stephane Demiguel, Paris (FR)

(21) Appl. No.: 13/312,953

(22) Filed: Dec. 6, 2011

(30) Foreign Application Priority Data
Dec. 7, 2010 (FR) 10 04754

(51) Int. Cl. H01L 31/02

(52) U.S. Cl. 257/443; 438/57; 257/E31.113

(57) ABSTRACT

The invention concerns a method for fabricating at least one detector pixel cell (45) connected to an element (82) formed in a weakly doped silicon substrate (81), characterized in that it comprises:
firstly, a first step to fabricate at least one layer (61) by implantation doping and activation annealing,
secondly, a second step to fabricate at least one connection node (85) in a circuit (83), from an element (82) formed in the substrate (81) by dry etching and metallization,
a step to combine, by bonding, the fabricated doped layer (61) with the fabricated connection node (85); and
a step to individualize at least one pixel cell (45) in the doped layer (61) by dry etching; and
a passivation and opening step opposite the individualized cell (45), by dry etching.

The invention also comprises a sensor including at least one such cell.

### GENERAL TECHNICAL FIELD

The present invention concerns a method for fabricating at least one detector pixel cell connected to an element formed in a substrate of weakly doped silicon.

The invention also comprises a sensor comprising at least one such cell.

### STATE OF THE ART

As shown in FIG. 1, a known intensified camera 10 generally comprises a lens 11 and a light amplifying tube 12 possibly of EBCMOS type (Electron Bombarded Complementary Metal Oxide Semiconductor) or EBCCD type (Electron Bombarded Charge-Coupled Device).

The tube 12 comprises an optical window 25 and a photocathode 15 which, under the effect of incident photons, emits electrons in a vacuum chamber 16. The electrons are accelerated towards a sensor array 20 by a potential difference VA, e.g. 2 Kv, between the photocathode 15 and the sensor array 20, generated by an adapted power supply 19. The chamber 16 allows the arrangement of connection wires 26 of the sensor 20 to connection pads 27. The tube 12 also comprises a support 38 and electric conductors 30 connected to the pads 27, to connect the sensor 20 with electronics of the intensified camera 10, and a body 35 of the tube 12 between the optical window 25 and the support 38. A phenomenon of electron multiplication inside the sensor 20 ensures amplification of the signal.

A sensor 20 is known from FR 2 928 034 comprising, as illustrated FIG. 2, a substrate 40 in semiconductor material e.g. silicon which may be P-doped, on which an array of detection elements 45 is formed together with reader circuits 47 of the signals induced in the detection elements 45, by bombarding the accelerated electrons.

As shown in FIG. 3, the detection elements 45 are formed using CMOS technology in the form of photodiodes with deep PN junction, with a weakly N-doped well 60 which extends over a depth L. Each detection element 45 comprises a portion 61 that is highly N-doped on the surface, similar to that of the drain of a NMOS transistor. The sensor 20 further comprises a protective, electrically conductive layer protecting the reader circuits 47 against the incident electrons.

The conductive layer 50 defines windows 51 enabling the electrons to bombard the detection elements 45.

The layer 50 may also be brought to a potential VB:
negative relative to the potential of each detection element 45, to form a network of electrostatic micro-lenses tending to focus the incident electrons on the detection elements 45, or
positive relative to the potential of each detection element 45, to cause the electrons to diverge from the elements 45 so as to reduce the sensitivity of the sensor, which may be useful when light intensity is high.

The conductive layer 50 is formed by metallization using a standard CMOS fabrication process on an insulating layer in SiO₂. The conductive layer 50 is an aluminium layer for example having a thickness of at least 2.5 μm and up to 4 μm for example.

The conductive layer 50, when the sensor 20 is observed from the front perpendicular to its plane, covers the detection element 45 over a distance 1 defining an overlap, as can be seen in FIG. 3. This distance 1 is of the order of 0.5 μm for example. Said overlap provides protection of the space-charge region 49.

The sensor according to FR 2 928 034 has drawbacks however.

As pointed out, the sensor known from FR 2 928 034 is fabricated using a standard CMOS fabrication process.

However, FR 2 928 034 does not detail the importance of the strongly N-doped portion 61 on the surface which acts as passivation of the detection elements 45 subjected to electron bombardment. The impact of the thickness of the strongly doped region is all the more critical on the performance level of multiplied charge collection, the weaker the energy of the incident electrons. A simplified model (SPIE vol. 2172, A. Reinheimer and M. Blouke) shows that close to 90% of the multiplied signal is lost at 2 keV if this thickness is greater than 40 nm (see summary of calculations in the table below). A thickness of the order of 20 nm would be needed to collect close to 50% of the multiplied signal at 2 keV.

This means that the choice of CMOS technology carries great importance. CMOS technology must be carefully chosen otherwise a certain number of fabricated sensors will not meet the need for collection at low energy.

| Thickness of passivated layer | 15 nm | 20 nm | 30 nm | 40 nm |
|---|---|---|---|---|
| Quantity of multiplied | 59% | 48% | 27% | 12% |
| signal collected at 2 keV | | | | |

The sensor according to FR 2 928 034 also has another disadvantage: the overlap surface created by the standard CMOS fabrication process, in the sensor 20, reduces the effective surface of the detection windows 51.

### PRESENTATION OF THE INVENTION

The invention proposes overcoming at least one of these disadvantages.

For this purpose, a method is proposed according to the invention to fabricate at least one detector pixel cell connected to an element formed in a weakly doped silicon substrate, characterized in that it comprises:
firstly, a first step for fabricating at least one layer doped by implantation doping and activation annealing;
secondly, a second step for fabricating at least one connection node in a circuit, from an element formed in a weakly doped silicon substrate, by dry etching and metallization,
a step for combining, by bonding, the fabricated doped layer with the fabricated connection node;
a step to individualize at least one pixel cell in the doped layer by dry etching, and
a step to passivate the cell, then to open a detection window by dry etching.

The invention is advantageously completed by the following characteristics taken alone or in any technically possible combination thereof:
the first fabrication step comprises the steps of:
   depositing an initial doped layer on a first handle in silicon,
   implanting the doped layer on the initial doped layer by implantation doping, and activation of the layer doped by implantation doping and activation annealing,
   transferring the doped layer onto a second handle in silicon,
   removing the first handle from the initial doped layer; and
   implanting a complementary dope layer on the initial doped layer, by implantation doping and activation of the complementary layer by activation annealing;
the second fabrication step comprises the steps of:
   forming at least one metal pad on the element in the weakly doped silicon substrate underneath a CMOS circuit;
   forming at least one channel in the circuit from the element, by dry etching, and
   forming a connection node in the channel by metallization.
the first fabrication step comprises a step to deposit a planarized metallization layer; and the second fabrication step comprises a step to deposit a planarized metallization layer, the step combining the fabricated layer with the fabricated connection node is conducted by bonding the said planarized metallization layers to form a final metal layer;
the passivation step is performed by growth of a dielectric layer;
the passivation step is performed by growth of a passivation layer in silicon oxide;
the steps of activation annealing are performed either by laser or by ultraviolet;
the implanting of the doped layer is performed by P+ implantation doping on the initial weakly P-doped layer; and the implanting of the complementary dope layer is performed by N+ implantation doping, the element then being N-type doped and being formed in a substrate in P-type weakly doped silicon;
the implanting of the doped layer is performed by N+ implantation doping on the initial weakly N-doped layer; and the implanting of the complementary dope layer is performed by P+ implantation doping, the element then being P-type doped and being formed in a substrate in N-type weakly doped silicon.

The invention also concerns a sensor comprising at least one said cell. The method of the invention can advantageously be applied, but not limited thereto, to the fabrication of a sensor for an intensified camera.

The invention has numerous advantages.

The method for fabricating the detector pixel cell according to the invention is not dependent on, nor limited by the standard CMOS fabrication process. The different layers and elements which can be obtained are therefore of finer thickness than in the prior art, in particular less than 2.5 μm.

In this case, the surface doped portion, of the detection elements can be strongly N+ or P+ doped independently of the chosen CMOS technology, and may have a thickness as narrow as possible and preferably less than 20 nm.

In addition, the overlap in the sensor created by a method according to the invention is lesser than the overlap in the prior art, which increases the effective surface area of the detection windows of the sensor.

Finally, the sensor array comprising a plurality of detector pixel cells derived from the fabrication method of the invention also allows a reduction in cross-talk between pixels.

### PRESENTATION OF THE FIGURES

Other characteristics, objectives and advantages of the invention will become apparent from the following description which is purely illustrative and non-limiting and is to be read with reference to the appended drawings in which:

FIG. 1, already discussed, schematically illustrates a known intensified camera;

FIGS. 2 and 3, already discussed, schematically illustrate a sensor and detection elements respectively known from FR 2 928 034;

FIG. 4 schematically illustrates a first fabrication step of at least one doped layer by implantation doping and activation annealing;

FIG. 5 schematically illustrates a second step for fabricating at least one connection node in a circuit, from an element formed in a weakly doped silicon substrate, by dry etching and metallization,

FIG. 6 schematically illustrates a step to combine, by bonding, the fabricated doped layer with the fabricated connection node, and at least one individualization step to individualize at least one pixel cell in the doped layer by dry etching;

FIG. 7 schematically illustrates an example of a pixel cell fabricated using a process according to the invention; and

FIG. 8 schematically illustrates a pixel cell in a sensor array, in particular for an intensified camera.

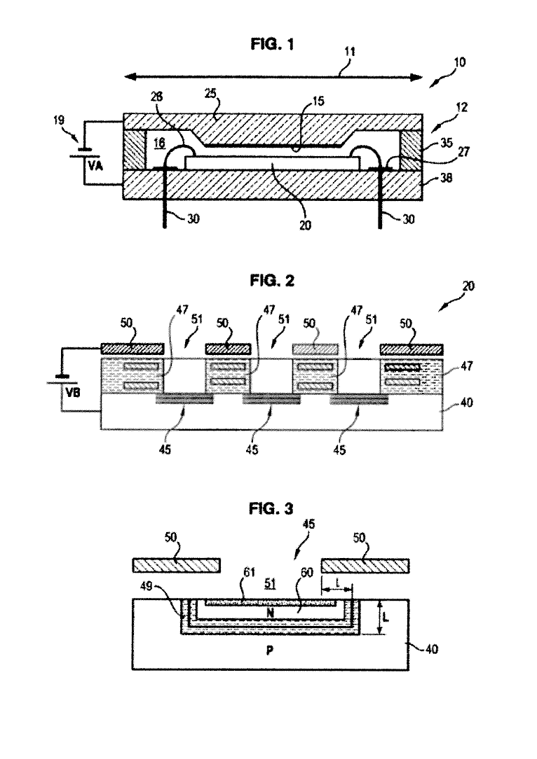

In all the figures, similar elements carry identical reference numbers.

### DETAILED DESCRIPTION

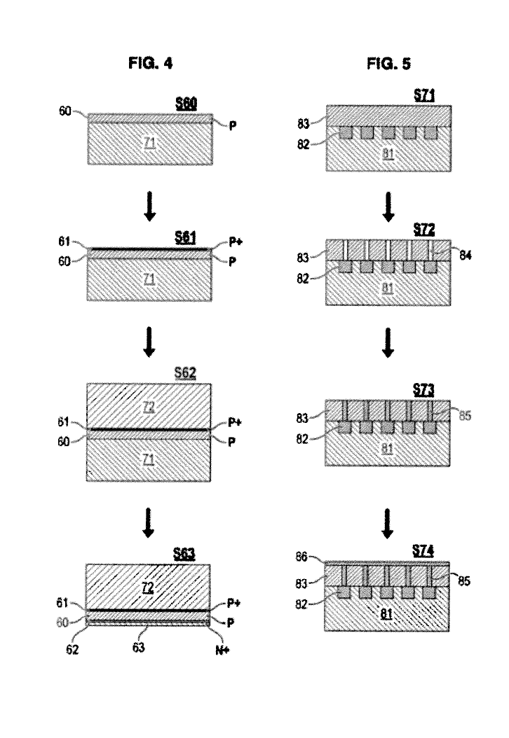

FIGS. 4, 5 and 6 schematically illustrate the main steps of a possible method for fabricating at least one detector pixel cell 45 connected to an element 82 formed in a weakly doped silicon substrate 81.

As will be seen in the remainder of the present description, by pixel cell is meant an individualized component, for example possibly being associated with a plurality of other cells of the same type to form an array. The cell is said to be a detector cell since it can be sensitive to a photon or to a high energy particle (e.g. an electron) such as typically a detection element in a sensor of an intensified camera.

Each element 82 is connected to a cell 45. It will be understood that if the cells 45 form an array, then the elements 82 also form an array.

The element 82 is preferably a doped region with complementary doping to the doping of the substrate 81 and is metallized.

The substrate 81 is preferably covered with a CMOS circuit 83.

The circuit 83 may also be of another type, for example of CDD type.

The method chiefly comprises firstly a first step S60-S63 to fabricate at least one doped layer 61 (see FIG. 4) and secondly a second step referenced S72-S73 (see FIG. 5) to fabricate at least one connection node 85 in the circuit 83, from the element 92 formed in the substrate 81.

As can be seen in FIG. 4, the first fabrication step more precisely comprises:
a step S60 to deposit an initial doped layer 60 on a first handle 71 in silicon;
a step S61 to implant the doped layer 61 on the initial doped layer 60;
a step S62 to transfer the doped layer 61 onto a second handle 72 in silicon;
a step S63 to remove the first handle 71 from the initial doped layer 60;
a step S63 to implant a complementary dope layer 62 on the initial doped layer 60 in lieu and stead of the first handle 71, and
a step S63 to activate the complementary layer 62.

The step S60 to deposit the initial layer 60 is conducted using conventional silicon-on-insulator technology, SOI, known to persons skilled in the art. The first handle 71 and the second handle 72 are in fact of Si semiconductor type. The different bonding operations between the layer 60 and the handle 71 are of conventional molecular bonding type.

The handles 71 and 72 facilitate the handling of the different layers.

By means of the deposit technology used i.e. SOI technology and not CMOS technology as in the prior art, the initial layer 60 may have a thickness e0 (see FIG. 8) of submicron size (typically a few hundred nanometres) which is much finer than obtained in the prior art, namely greater than 2.5 μm.

Steps S61 and S63 are performed by implantation doping followed either by activation annealing using low temperature laser, or by UV flash annealing at 600-800° C. (ultra-violet).

By means of the technology used, i.e. implantation doping and activation annealing and not CMOS technology as in the prior art, the doped layer 61 may have a thickness e1 (see FIG. 8) preferably less than 20 nm, adjustable independently of CMOS technology.

Also, as can be seen in FIG. 5, the second fabrication step more precisely comprises:
a step S71 to form metal pads on the elements 82 in the substrate 81, the substrate 81 preferably being covered with a CMOS circuit 83;
a step S72 to form a channel 84 in the circuit 83 from each element 82; and
a step S73 to form a connection node 85 in the channel 84.

Step S71 to form the pad in the substrate is conducted as is conventional using CMOS technology known to persons skilled in the art. The assembly 81-82-83 in this case is commercially available.

Step S72 is preferably performed by dry etching.

Step S73 is preferably performed by metallization.

As can be seen in FIGS. 4 and 5, the first fabrication step also comprises a step S63 to deposit a planarized metallization layer 63 on layer 62, and the second fabrication step comprises a step S74 to deposit a planarized metallization layer 86 on the circuit 83 in order to facilitate a step S81 to combine the fabricated doped layer 62 with the fabricated connection node 85.

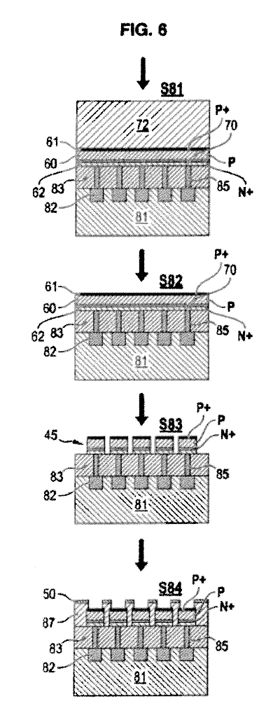

The combining is preferably performed at a step by metal/metal bonding of the planarized metallization layers 63 and 68 to form a final metal layer 70 (see FIG. 6).

The process further comprises a step S82 to remove the second handle 72.

It also comprises an individualization step S83 to individualize at least one pixel cell 45 in the layer 61 thus released from the second handle 72.

Individualization is performed by dry etching.

The method also comprises a passivation step S84 which is performed by growth of a dielectric layer, by depositing a layer 87 preferably of silicon oxide, and a metallization step S84 by depositing a layer 50.

The method finally comprises a step S84 to open a detection window 51 opposite the individualized cell 45, by dry etching.

The dimension φ of the window 51 (see FIG. 8) may extend to the size of the pixel 45 independently of the space taken up by the electronics of the pixel (for example, transistors in CMOS technology) but the dimension φ is reduced by the design rules imposed by the lithography means used (which may however be submicron). Therefore, the distance between two neighbouring windows may be less than one micrometer, which increases the effective surface area of the detection windows compared with the prior art.

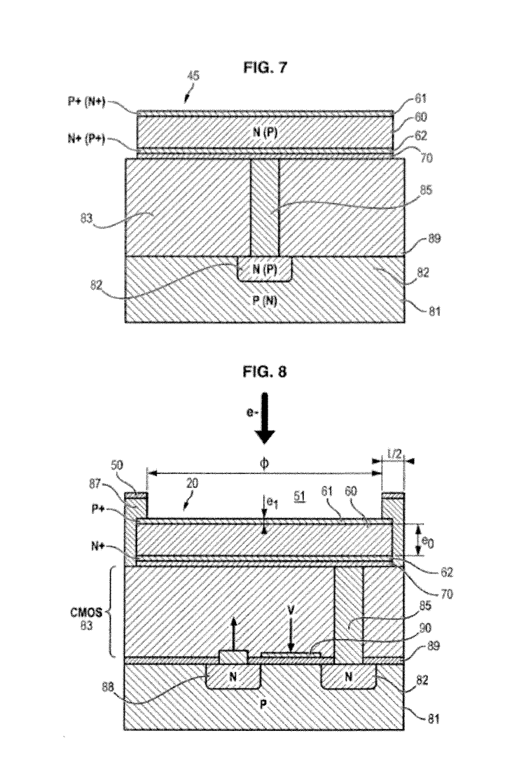

As shown in FIG. 7, the implanting of the doped layer 61 is conducted by P+ implantation doping on the initial P-doped layer 60; and the implantation of the complementary dope layer 62 is performed by N+ implantation doping. In this case, the element 82 is N-type doped and is formed in a silicon substrate 81 of weakly P-doped type.

According to one possible variant as shown in FIG. 7 between brackets, the implanting of the doped layer 61 is conducted by N+ implantation doping on the initial N-doped layer 60; and the implanting of the complementary dope layer 62 is performed by P+ implantation doping. In this case the element 82 is P-type doped and is formed in a silicon substrate 81 that is weakly N-type doped.

As shown in FIG. 8, the detector pixel cells fabricated using a method of the invention preferably, but not limited thereto, form detection elements 45 used in sensors of intensified cameras.

For this purpose and as shown in FIG. 8, in addition to the elements already described the sensor as is conventional comprises:
a charge storage node 88 of complementary doping to the substrate 81 (N-doped node if the substrate 81 is P-doped, and conversely P-doped node if the substrate 81 is N-doped) for connection to pixel electronics, and
on an oxide 89, a connection 90 to a transfer potential.

It is repeated that the use as sensor in an intensified camera is only one example, and the windows may be sensitive to photons for example and can therefore be used in any type of sensor array.

1. Method for fabricating at least one detector pixel cell (45) connected to an element (82) formed in a weakly doped silicon substrate (81), comprising:
firstly, a first step (S60-S63) to fabricate at least one layer (61) doped by implantation doping and activation annealing,
secondly, a second step (S71-S73) to fabricate at least one connection node (85) in a circuit (83), from an element (82) formed in a weakly doped silicon substrate (81) by dry etching and metallization,
a step (S81) to combine, by bonding, the fabricate doped layer (61) with the fabricated connection node (85);
a step (S83) to individualize at least one pixel cell (45) in the doped layer (61) by dry etching; and
a step (S84) to passivate the cell (45) by growth of a dielectric layer (87), then to open a detection window (51) by dry etching opposite the cell (45),
wherein the first fabrication step comprises the steps of:
depositing (S60) an initial doped layer (60) on a first handle (71) in silicon;
implanting (S61) the doped layer (61) on the initial doped layer (60) by implantation doping, and activation (S62) of the layer (61) doped by implantation doping, and activation annealing;
transferring (S62) the doped layer (61) onto a second handle (72) in silicon,
removing (S63) the first handle (71) from the initial doped layer (60); and
implanting (S63) a complementary doped layer (62) on the initial doped layer (60) by implantation doping, and activating (S63) the complementary layer (62) by activation annealing.

2. The method according to claim 1 wherein the second fabrication step comprises the steps of:
forming (S71) at least one metal pad on the element (82) in the weakly doped silicon substrate (81) underneath a CMOS circuit (83);
forming (S72) at least one channel (84) in the circuit (83) from the element (82), by dry etching; and
forming (S73) a connection node (85) in the channel (84) by metallization.

3. The method according to one of claims 1 to 2 wherein:
the first fabrication step comprises a step to deposit a planarized metallization layer (63); and
the second fabrication step comprises a step to deposit a planarized metallization layer (86);
the combining step (S81) to combine the fabricated layer (82) with the fabricated connection node (85) is performed by bonding the said planarized metallization layers (63, 86) to form a final metal layer (70).

4. The method according to claim 1 wherein the passivation step is performed by growth of a passivation layer (87) in silicon oxide.

5. The method according to one of claims 1 to 2, wherein the activation annealing steps are performed either by laser or by ultra-violet.

6. The method according to one of claims 1 to 2 wherein the implanting (S62) of the doped layer (61) is performed by P+ implantation, doping on the initial weakly P-doped layer (60); and the implanting (S64) of the complementary doped layer (62) is performed by N+ implantation doping, the element (82) then being N-type doped and being formed in a weakly P-type doped silicon substrate (81).

7. The method according to one of claims 1 to 2 wherein the implanting (S62) of the doped layer (61) is conducted by N+ implantation doping on the initial weakly N-doped layer (60); and the implanting (S64) of the complementary doped layer (62) is performed by P+ implantation doping, the element (82) then being P-type doped and being formed in a weakly N-type doped silicon substrate (81).

8. A sensor array (20) comprising a plurality of detector pixel cells (45) fabricated according to one of claims 1 to 2.
